(19) United States
(12) Patent Application Publication
(10) Pub. No.: US 2007/0096115 A1
(43) Pub. Date: May 3, 2007

(54) Nitride-based semiconductor light emitting diode

(76) Inventors: Hyuk Min Lee, Seoul (KR); In Joon Pyeon, Suwon (KR); Hyun-Ju Park, Suwon (KR); Hyun Kyung Kim, Suwon (KR); Dong Joon Kim, Suwon (KR); Hyoun Soo Shin, Seoul (KR)

Correspondence Address: MCDERMOTT WILL & EMERY LLP, 600 13TH STREET, N.W., WASHINGTON, DC, 20005-3096, US

(21) Appl. No.: 11/581,757

(22) Filed: Oct. 17, 2006

(30) Foreign Application Priority Data
Oct. 17, 2005 (KR) 10-2005-0097412

(51) Int. Cl. H01L 33/00; H01L 31/12; H01L 27/15; H01L 29/26

(52) U.S. Cl. 257/79

(57) ABSTRACT

A nitride-based semiconductor LED comprises a substrate; an n-type nitride semiconductor layer formed on the substrate; an active layer formed on a predetermined region of the n-type nitride semiconductor layer; a p-type nitride semiconductor layer formed on the active layer; a current spreading layer formed on the p-type nitride semiconductor layer; a p-electrode formed on the current spreading layer, the p-electrode having two p-type branch electrodes; and an n-electrode formed on the n-type nitride semiconductor layer on which the active layer is not formed, the n-electrode having one n-type branch electrode. The n-type branch electrode is formed so as to be inserted between two of the p-type branch electrodes, and a distance from the outermost side of a transparent electrode adjacent to the n-electrode to the p-electrode is identical at any position.

### CROSS-REFERENCE TO RELATED APPLICATIONS

This application claims the benefit of Korean Patent Application No. 2005-97412 filed with the Korea Industrial Property Office on Oct. 17, 2005, the disclosure of which is incorporated herein by reference.

### BACKGROUND OF THE INVENTION

1. Field of the Invention

The present invention relates to a nitride-based semiconductor light emitting diode (LED) which can implement a low driving voltage in an LED chip having the same unit area.

2. Description of the Related Art

Since nitride-based semiconductors such as GaN and the like have excellent physical and chemical properties, they are considered as essential materials of light emitting diodes, for example, light emitting diodes (LEDs) or laser diode (LDs). As the nitride-based semiconductors, materials having a compositional formula of In_{X}Al_{Y}Ga_{1-X-Y}N (0≦X, 0≦Y, X+Y≦1) are widely used.

Conventionally, the nitride-based semiconductor LED is composed of square-shaped LED chips in order to enhance current spreading efficiency. Recently, however, the length of the X or Y axis of the chip is gradually reduced in the case of a side-view surface mounting package, thereby forming rectangle-shaped LED chip.

In the rectangle-shaped LED chip, however, a luminous area corresponding to a certain area required for light-emission is reduced due to the reduction in length of the X or Y axis and contact resistance increases, thereby increasing a driving voltage.

Hereinafter, the problems of a conventional nitride-based semiconductor LED will be described in detail with reference to FIG. 1.

FIG. 1 is a diagram for explaining the problems of the conventional nitride-based semiconductor LED, explaining a change in driving voltage in accordance with a change in size of a rectangle-shaped LED chip.

Referring to FIG. 1, the conventional nitride semiconductor LED is formed in various shapes of (A) to (D) in accordance with a change in lengths of X and Y axes of a rectangle-shaped LED chip. As the size of the LED chip varies from (D) to (A), that is, as the rectangle-shaped LED chip is gradually reduced in size, the magnitude of a driving voltage (V) gradually increases.

More specifically, when the chips (A) and (C) having the same X-axis length of 610 μm and different Y-axis lengths of 210 μm and 300 μm, respectively, are compared with each other, the driving voltage of the chip (A) having a Y-axis length of 210 μm is larger than that of the chip (C) having a Y-axis length of 300 μm.

When the chip (C) and (D) having different X-axis lengths of 610 μm and 660 μm, respectively, and the same Y-axis length of 300 μm are compared with each other, the driving voltage of the chip (C) having an X-axis length of 610 μm is larger than that of the chip (D) having an X-axis length of 660 μm.

In the conventional rectangle-shaped LED chip, a luminous area is reduced, as the X or Y-axis length decreases. That is, as the rectangle-shaped LED chip is reduced in size, a driving voltage increases.

Therefore, such a technique that can enhance a driving voltage of the rectangle-shaped LED chip is continuously required to be developed.

### SUMMARY OF THE INVENTION

An advantage of the present invention is that it provides a nitride-based semiconductor LED in which a distance between a p-electrode and an n-electrode is maintained to be identical so as to enhance current spreading efficiency, thereby implementing a lower driving voltage in an LED chip with the same unit area.

Additional aspect and advantages of the present general inventive concept will be set forth in part in the description which follows and, in part, will be obvious from the description, or may be learned by practice of the general inventive concept.

According to an aspect of the invention, a nitride-based semiconductor LED comprises a substrate; an n-type nitride semiconductor layer formed on the substrate; an active layer formed on a predetermined region of the n-type nitride semiconductor layer; a p-type nitride semiconductor layer formed on the active layer; a current spreading layer formed on the p-type nitride semiconductor layer; a p-electrode formed on the current spreading layer, the p-electrode having two p-type branch electrodes; and an n-electrode formed on the n-type nitride semiconductor layer on which the active layer is not formed, the n-electrode having one n-type branch electrode. The n-type branch electrode is formed so as to be inserted between two of the p-type branch electrodes, and a distance from the outermost side of a transparent electrode adjacent to the n-electrode to the p-electrode is identical at any position.

According to another aspect of the invention, the p-electrode is formed to be spaced at a predetermined distance from the outermost side of the transparent electrode.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a diagram for explaining the problems of the conventional nitride-based semiconductor LED;

FIG. 2 is a plan view illustrating the structure of a nitride-based semiconductor LED according to an embodiment of the invention;

FIG. 3 is a sectional view taken along III-III′ line of FIG. 2;

FIG. 4 is a photograph showing that the nitride-based semiconductor LED shown in FIG. 2 emits light;

FIG. 5 is a diagram for explaining a change in driving voltage in accordance with the chip size of the nitride semiconductor LED according to the invention; and

FIG. 6 is a diagram comparatively showing the brightness of the nitride-based semiconductor LED according to the invention with the brightness of the conventional nitride-based semiconductor LED.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a nitride-based semiconductor LED according to an embodiment of the present invention will be described in detail with reference to the accompanying drawings.

Referring to FIGS. 2 to 4, the structure of the nitride-based semiconductor LED will be described in detail.

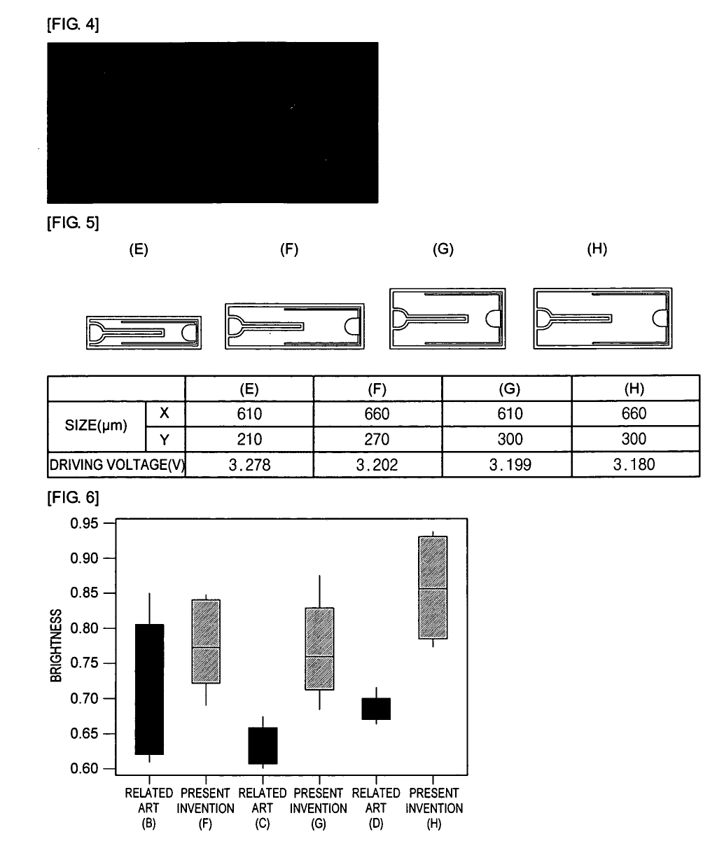

FIG. 2 is a plan view illustrating the structure of the nitride-based semiconductor LED according to the embodiment of the invention, FIG. 3 is a sectional view taken along III-III′ line of FIG. 2, and FIG. 4 is a photograph showing that the nitride-based semiconductor LED shown in FIG. 2 emits light.

Referring to FIGS. 2 and 3, the nitride-based semiconductor LED according to the invention includes an optically-transparent substrate 100 and a light-emitting structure in which a buffer layer 100, an n-type nitride semiconductor layer 120, an active layer 130, and a p-type nitride semiconductor layer 140 are sequentially laminated on the substrate 100.

The substrate 100 is suitable for growing nitride semiconductor single crystal. Preferably, the substrate 100 is formed of a transparent material containing sapphire. In addition to sapphire, the substrate 100 may be formed of zinc oxide (ZnO), gallium nitride (GaN), silicon carbide (SiC) and aluminum nitride (AlN).

The buffer layer 110 is a layer for enhancing the lattice matching with the sapphire substrate 110 before the n-type nitride semiconductor layer 120 is grown on the substrate 100. The buffer layer 110 is formed of AlN/GaN.

The n-type and p-type nitride semiconductor layers 120 and 140 and the active layer 130 can be formed of a semiconductor material having a composition of In_{X}Al_{Y}Ga_{1-X-Y}N (here, 0≦X, 0≦Y, and X+Y≦1). More specifically, the n-type nitride semiconductor layer 120 can be formed of a GaN or GaN/AlGaN layer doped with n-type conductive impurities. For example, the n-type conductive impurity may be Si, Ge, Sn and the like, among which Si is preferably used. Further, the p-type nitride semiconductor layer 140 can be formed of a GaN or GaN/AlGaN layer doped with p-type conductive impurities. For example, the p-type conductive impurity may be Mg, Zn, Be and the like, among which Mg is preferably used. The active layer 130 can be formed of an InGaN/GaN layer with a multi-quantum well structure.

The active layer 130 may be formed with one quantum well layer or a double-hetero structure.

Further, portions of the active layer 130 and the p-type nitride semiconductor layer 140 are removed by mesa etching, so that the upper surface of the n-type nitride semiconductor layer 120 formed on the bottom surface is partially exposed.

On the exposed n-type nitride semiconductor layer 120, an n-electrode 160 is formed. The n-electrode 160 according to this embodiment has one n-type branch electrode 160′ for enhancing a current spreading effect.

On the p-type nitride semiconductor layer 140, a transparent electrode 170 is formed. In this case, the transparent electrode 170 may be formed of a metallic thin film having high conductivity and low contact resistance as well as a conductive metallic oxide such as ITO (Indium Tin Oxide), if the metallic thin film has high transmittance with respect to an emission wavelength of the LED.

When the transparent electrode 170 is formed of a metallic thin film, it is preferable that the thickness of the metallic film is maintained to be less than 50 μm in order to secure transmittance. For example, the transparent electrode 170 may have such a structure that a Ni layer with a thickness of 10 μm and an Au layer with a thickness of 40 μm are sequentially laminated.

On the transparent electrode 170, a p-electrode 150 is formed. The p-electrode 150 according to this embodiment has two p-type branch electrodes 150′ for enhancing a current spreading effect.

Two of the p-type branch electrodes 150′ are formed along the outermost side of the transparent electrode 170 so as to minimize local current crowding which occurs when the surface resistance Rs of the transparent electrode 170 is larger than that of the n-type nitride semiconductor layer 120. At this time, the positional relationship between the p-type branch electrodes 150′ and the n-type branch electrode 160′ is where the n-type branch electrode 160′ is inserted between two of the p-type branch electrodes 150′.

In this embodiment, a distance from the outermost side of the transparent electrode 170 adjacent to the n-electrode 160 to the p-type electrode 150 is identical at any position of the p-electrode 150, in order to minimize local current crowding which occurs due to a difference in surface resistance Rs between the transparent electrode 150 and the n-type nitride semiconductor layer 120. For example, it is preferable that distances a, b, c, d and e are identical to each other, as shown in FIG. 2.

As a result, the current spreading efficiency of the nitride-based semiconductor LED according to the invention is enhanced. Accordingly, a driving voltage of an LED, which increases as rectangular LED chips are reduced in size, can be reduced so as to secure an excellent driving voltage characteristic. When a driving voltage is reduced, power consumption can be also reduced. Therefore, when a nitride-based semiconductor LED is driven, heat which is unnecessarily generated can be reduced, which makes it possible to minimize the degradation of the LED.

Hereinafter, the n-electrode 160 and the p-electrode 150 according to the invention will be described with reference to FIGS. 5 and 6.

FIG. 5 is a diagram for explaining a change in driving voltage in accordance with the chip size of the nitride semiconductor LED according to the invention, and FIG. 6 is a diagram comparatively showing the brightness of the nitride-based semiconductor LED according to the invention with the brightness of the conventional nitride-based semiconductor LED.

Referring to FIG. 5, the nitride-based semiconductor LED according to the invention can be formed in various shapes of (E) to (H), as the X-axis and Y-axis lengths of the rectangular LED chip vary. As the size of the LED chip varies from (H) to (E), that is, as the LED chip is gradually reduced in size, the magnitude of a driving voltage (V) gradually increases.

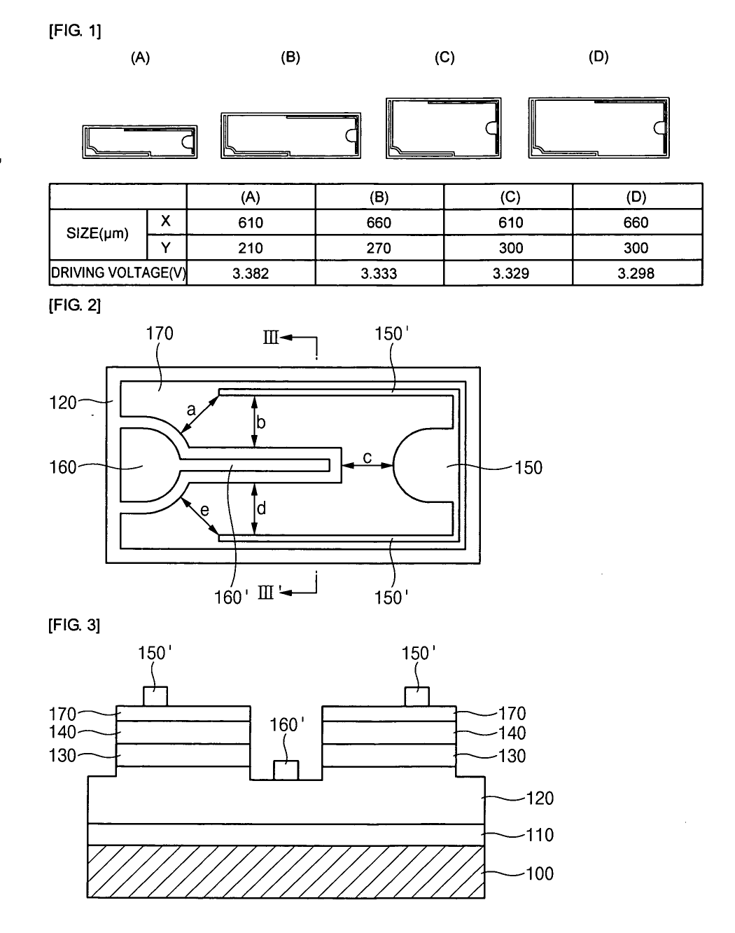

However, the nitride-based semiconductor LED having such a structure that one electrode is inserted into the other electrode has a smaller driving voltage than the conventional nitride-based semiconductor LED (refer to FIG. 1) having the same chip size.

As such, when the magnitude of a driving voltage decreases, the current spreading efficiency is also enhanced, so that the brightness of the nitride-based semiconductor LED becomes excellent.

FIG. 6 is a diagram comparatively showing the brightness of the nitride-based semiconductor LED according to the invention with the brightness of the conventional nitride-based semiconductor LED. In FIG. 6, the brightnesses of the chips (B) and (F) having an X-axis length of 660 μm and a Y-axis length of 270 μm, the brightnesses of the chips (C) and (G) having an X-axis length of 610 μm and a Y-axis length of 300 μm, and the brightnesses of the chips (D) and (H) having an X-axis length of 660 μm and a Y-axis length of 300 μm are respectively compared with each other. At this time, the chips (B), (C), and (D) are the conventional nitride-based semiconductor LEDs, and the chips (F), (G), and (H) are the nitride-based semiconductor LEDs according to the invention.

Referring to FIG. 6, it can be found that the brightness of the nitride-based semiconductor LED according to the invention is more excellent than that of the conventional nitride-based semiconductor LED.

According to the present invention, the branch electrodes of the p-electrode are disposed on the transparent electrode along the outermost side of the transparent electrode, thereby minimizing local current crowding which occurs due to a difference in surface resistance between the transparent electrode and the n-type nitride semiconductor layer.

Further, in order to enhance the current spreading efficiency, the n-electrode is inserted between the branch electrodes of the p-electrode so as to be spaced from each other, and a distance between the p-electrode and the n-electrode is maintained to be identical at any position, thereby enhancing current spreading efficiency. Therefore, it is possible to provide such a nitride-based semiconductor LED that can implement a low driving voltage within the same chip size.

Accordingly, the brightness of the nitride semiconductor LED can be enhanced and the degradation thereof can be prevented, which makes it possible to enhance the characteristics and reliability of the LED.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride-based semiconductor LED comprising:
a substrate;
an n-type nitride semiconductor layer formed on the substrate;
an active layer formed on a predetermined region of the n-type nitride semiconductor layer;
a p-type nitride semiconductor layer formed on the active layer;
a current spreading layer formed on the p-type nitride semiconductor layer;
a p-electrode formed on the current spreading layer, the p-electrode having two p-type branch electrodes; and
an n-electrode formed on the n-type nitride semiconductor layer on which the active layer is not formed, the n-electrode having one n-type branch electrode,
wherein the n-type branch electrode is formed so as to be inserted between two of the p-type branch electrodes, and a distance from the outermost side of a transparent electrode adjacent to the n-electrode to the p-electrode is identical at any position.

2. The nitride-based semiconductor LED according to claim 1,
wherein the p-electrode is formed to be spaced at a predetermined distance from the outermost side of the transparent electrode.
